(19) United States
(12) Patent Application Publication
(10) Pub. No.: US 2026/0305045 A1
(43) Pub. Date: Oct. 1, 2026

(54) LIGHTING EMITTING DIODE PACKAGE STRUCTURE

(71) Applicant: Ennostar Corporation, Hsinchu City (TW)

(72) Inventor: Shiou-Yi KUO, Hsinchu (TW)

(21) Appl. No.: 19/630,007

(22) Filed: Mar. 26, 2026

(30) Foreign Application Priority Data
Mar. 27, 2025 (TW) 114111888

(51) Int. Cl. H10H 29/85; H10H 29/851

(52) U.S. Cl. CPC H10H 29/857; H10H 29/8508; H10H 29/8514

(57) ABSTRACT

The present disclosure provides a light emitting diode package, which includes an insulating layer, a plurality of light emitting diodes, a circuit layer, a plurality of bonding pads, and a light conversion layer. The insulating layer has a process working region, and an area of the process working region is 2% to 50% of an area of the insulating layer. The light emitting diodes are embedded in the insulating layer, and the light emitting diodes are arranged around the process working region. The circuit layer is embedded in the insulating layer and electrically connected to the light emitting diodes. The bonding pads are disposed under the insulating layer and electrically connected to the circuit layer. The light conversion layer is disposed on the insulating layer. The process working region overlaps with a geometric center of the light emitting diode package in a top view.

### CROSS-REFERENCE TO RELATED APPLICATION

This application claims priority to Taiwan Application Serial Number 114111888, filed Mar. 27, 2025, which is herein incorporated by reference in its entirety.

### BACKGROUND

### Field of Invention

The present disclosure relates to light emitting diode package. More particularly, the present disclosure relates to a thinning light emitting diode package.

### Description of Related Art

With the rapid development of electronic devices, various components in the electronic devices are gradually being miniaturized (scaling down). Taking the packaging structure of light emitting diodes as an example, the reduction in the size of the light emitting diodes greatly increases the difficulty of the manufacturing process, thereby leading to problems such as poor yield. Therefore, although the existing LED packaging structures have gradually satisfied their intended uses, they do not meet the requirements in all aspects. Therefore, there are still some problems to be overcome regarding the LED packaging structure.

### SUMMARY

The disclosure provides a light emitting diode package, which can increase the process yield and improve the light emitting efficiency. The light emitting diode package includes an insulating layer, a plurality of light emitting diodes, a circuit layer, a plurality of bonding pads, and a light conversion layer. The insulating layer has a process working region, and an area of the process working region is 2% to 50% of an area of the insulating layer. The light emitting diodes are embedded in the insulating layer, and the light emitting diodes are arranged around the process working region. The circuit layer is embedded in the insulating layer and electrically connected to the light emitting diodes. The bonding pads are disposed under the insulating layer and electrically connected to the circuit layer. The light conversion layer is disposed on the insulating layer. The process working region overlaps with a geometric center of the light emitting diode package in a top view.

The disclosure provides a light emitting diode package, which can increase the process yield and improve the light emitting efficiency. The light emitting diode package includes an insulating layer, a plurality of light emitting diodes, a circuit layer, a plurality of bonding pads, and a light conversion layer. The insulating layer has a process working region, and an area of the process working region is 2% to 50% of an area of the insulating layer. The light emitting diodes are embedded in the insulating layer, and a vertical projection of any one of the plurality of light emitting diodes does not overlap with a vertical projection of the process working region. The circuit layer is embedded in the insulating layer and electrically connected to the light emitting diodes. The bonding pads are disposed under the insulating layer and electrically connected to the circuit layer. The light conversion layer is disposed on the insulating layer. The process working region overlaps with a geometric center of the light emitting diode package in a top view.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a cross-sectional view of a light emitting diode package according to various embodiments of the present disclosure.

FIG. 2 is a top view of a light emitting diode package according to various embodiments of the present disclosure.

FIG. 3 is a bottom view of a light emitting diode package according to various embodiments of the present disclosure.

FIG. 4 is a cross-sectional view of a light emitting diode package according to various embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

The following embodiments are disclosed with accompanying diagrams for a detailed description. For illustration clarity, many details of practice are explained in the following descriptions. However, it should be understood that these details of practice do not intend to limit the present disclosure. That is, these details of practice are not necessary in parts of embodiments of the present disclosure. Furthermore, to simplify the drawings, some of the conventional structures and elements are shown with schematic illustrations.

In the specification, scopes represented by “a numerical value to another numerical value” are schematic representations in order to avoid listing all of the numerical values in the scopes in the specification. Therefore, the recitation of a specific numerical range covers any numerical value in the numerical range and a smaller numerical range defined by any numerical value in the numerical range, as is the case with any numerical value and a smaller numerical range thereof in the specification.

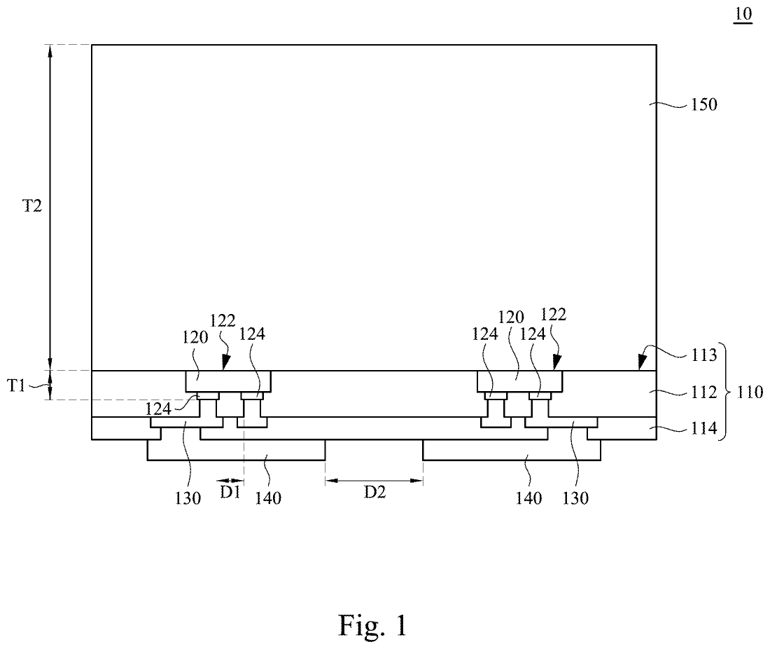

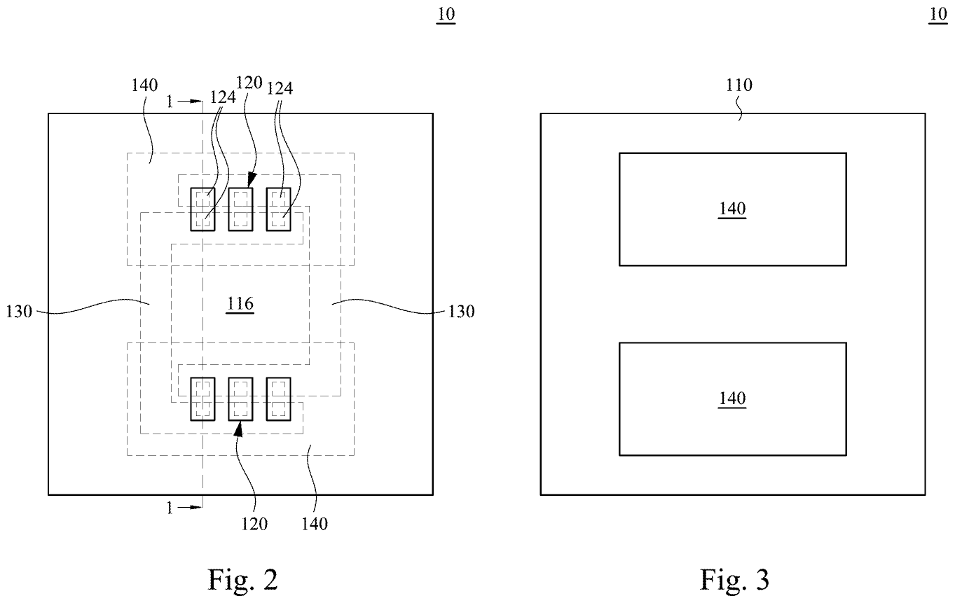

The present disclosure provides a light emitting diode packaging structure that can not only increase the process yield, but also improve the light emitting efficiency. FIG. 1 is a cross-sectional view of a light emitting diode package according to various embodiments of the present disclosure. FIG. 2 is a top view of a light emitting diode package according to various embodiments of the present disclosure. FIG. 3 is a bottom view of a light emitting diode package according to various embodiments of the present disclosure. More specifically, FIG. 1 is a cross-sectional view along the section line 1-1 in FIG. 2, and the light conversion layer is omitted in the top view of FIG. 2 to show the corresponding positions of other components more clearly.

Please refer to FIG. 1, FIG. 2 and FIG. 3 at the same time. The light emitting diode package 10 includes an insulating layer 110, a plurality of light emitting diodes 120, a circuit layer 130, a plurality of bonding pads 140 and a light conversion layer 150. To be specific, the plurality of light emitting diodes 120 are disposed in the insulating layer 110, and the light conversion layer 150 covers the insulating layer 110 and the plurality of light emitting diodes 120. The plurality of bonding pads 140 are located on a side of the insulation layer 110 opposite to the light conversion layer 150, such that the insulation layer 110 is disposed between the plurality of bonding pads 140 and the light conversion layer 150. The circuit layer 130 is disposed in the insulating layer 110 and is electrically connected to the plurality of light emitting diodes 120 and the plurality of bonding pads 140.

In some embodiments, the insulating layer 110 has a process working region 116, and the plurality of light emitting diodes 120 are symmetrically disposed around the process working region 116. It should be noted that the “process working region 116” described in the present disclosure is intended for use in handling the light emitting diode package during the manufacturing process. In one embodiment, the process working region is a working area when a jig or a fixture is operated during the process, e.g., the area where the jig or fixture contacts the product and/or semi-finished product. In this embodiment, no light emitting diode 120 may be disposed in the “process working region 116”. That is to say, the vertical projection of any one of the plurality of light emitting diodes 120 does not overlap with the vertical projection of the process working region 116, therefore preventing the light emitting diodes 120 from being damaging by the jig or fixture during process. In some embodiments, an area of the process working region 116 is 2% to 50% of total area of the insulating layer 110, such as 5%, 10%, 15%, 20%, 25%, 30%, 35%, 40%, 45%, or 50%. In some embodiments, when the area of the process working region 116 is greater than a certain value, such as 50%, it is difficult to dispose the light emitting diode 120 and the circuit layer 130. On the contrary, in some embodiments, when the area of the process working region 116 is less than a certain value, such as 2%, the light emitting diode 120 and/or the circuit layer 130 may be damaged by the operation of the jig or fixture during the manufacturing process. It should be noted that the process working region 116 overlaps with a geometric center of the light emitting diode package 10 in the top view, as shown in FIG. 2.

In some embodiments, the insulating layer 110 includes insulating materials, such as silicon oxide (SiO₂), aluminum oxide (Al₂O₃), titanium dioxide (TiO₂), hafnium dioxide (HfO₂), tantalum oxide (Ta₂O₅), silicon nitride (Si₃N₄), compounds of the foregoing materials, or combinations thereof, but the present disclosure is not limited to the above-mentioned examples. In some embodiments, the insulating layer 110 includes a first insulating layer 112 and a second insulating layer 114 which are stacked, and the first insulating layer 112 is disposed between the second insulating layer 114 and the light conversion layer 150. In some embodiments, the first insulating layer 112 or the second insulating layer 114 can reflect light emitted by the light emitting diodes 120, and the reflectivity of the first insulating layer 112 or the second insulating layer 114 is at least greater than 80%. For example, the first insulating layer 112 or the second insulating layer 114 may be a distributed Bragg reflector (DBR). The DBR may include a periodic structure formed by two material layers with different refractive indices arranged alternatively. For example, the distributed Bragg reflector can be composed of alternate stacks of SiO₂ and TiO₂ or alternate stacks of SiO₂/Al₂O₃/TiO₂. This design can increase the light emitting efficiency of the light emitting diode package 10. In some embodiments, the reflectivity of the first insulating layer 112 or the second insulating layer 114 to the light emitted by the light emitting diode 120 is not less than 80%, such as 80%, 85%, 90%, 95% or 99%.

Referring to FIG. 1, FIG. 2 and FIG. 3. The plurality of light emitting diodes 120 are embedded in the insulating layer 110, and the light emitting diodes 120 are separated from each other by the insulating layer 110. In some embodiments, the insulating layer 110 surrounds the plurality of light emitting diodes 120 and exposes a light emitting surface 122 of each of the plurality of light emitting diodes 120. In some embodiments, the light emitting diode 120 is a thin film light emitting diode without a substrate. In this case, the light emitting surface 122 of the light emitting diode 120 is the surface of the semiconductor layer. In some embodiments, the light emitting surface 122 of each light emitting diode 120 is leveled with an upper surface 113 of the insulating layer 110. In some embodiments, the plurality of light emitting diodes 120 is arranged around the process working region 116. For example, as shown in FIG. 2, the plurality of light emitting diodes 120 are spaced apart from each other and symmetrically arranged at any two opposite sides of the process working region 116. The number of the light emitting diodes 120 is preferably an even number, such as 2, 4, 6, 8, 10 or more, but the disclosure is not limited thereto. In some embodiments, the light emitting diodes 120 are embedded in the first insulating layer 112.

In some embodiments, each light emitting diode 120 has a thickness T1 of 3 micrometers to 20 micrometers. For example, the thickness T1 of each light emitting diode 120 may be 5 micrometers, 10 micrometers, or 15 micrometers. In some embodiments, when the thickness T1 of the light emitting diode 120 is greater than a certain value, such as 20 micrometers, the lateral light ratio of the light emitting diode 120 is increased and the axial brightness is reduced. On the contrary, when the thickness T1 of the light emitting diode 120 is less than a certain value, such as 3 micrometers, the difficulty of the manufacturing process will be greatly increased. In some embodiments, each light emitting diode 120 has a plurality of electrodes 124 disposed on a side opposite to the light conversion layer 150. In some embodiments, at least two of the plurality of electrodes 124 has different polarities, such as a positive electrode and a negative electrode.

Please continue to refer to FIGS. 1, 2 and 3. The circuit layer 130 is embedded in the insulating layer 110 and electrically connected to the plurality of light emitting diodes 120. In some embodiments, the circuit layer 130 is disposed along the interface between the first insulating layer 112 and the second insulating layer 114 and is embedded in the second insulating layer 114. The circuit layer 130 extends into the first insulating layer 112 to be electrically connected to the electrodes 124 of the plurality of light emitting diodes 120. In some embodiments, the plurality of light emitting diodes 120 form a series circuit, a parallel circuit, or independent circuits through the circuit layer 130.

In some embodiments, the circuit layer 130 includes a plurality of sub-circuits separated from each other. The electrodes 124 with different polarities in each light emitting diode 120 are electrically connected to different sub-circuits, and the number of sub-circuits may be determined according to circuit design requirements. For example, when it is desired that a plurality of light emitting diodes 120 can be controlled synchronously, the number of sub-circuits is the same as the number of polarities of the electrodes 124 of the light emitting diodes 120. For example, in this embodiment, each light emitting diode 120 has two electrodes 124 of different polarities, and the circuit layer 130 includes two sub-circuits, of which one of the sub-circuits is simultaneously connected to one of the electrodes 124 of each light emitting diode 120, and the other sub-circuit is simultaneously connected to the other electrode 124 of each light emitting diode 120, as shown in FIG. 2. However, when it is desired that the plurality of light emitting diodes 120 can be independently controlled, the number of sub-circuits will be greater than the number of the light emitting diodes 120.

In some embodiments, the circuit layer 130 includes a conductive material, such as copper (Cu), silver (Ag), aluminum (Al), nickel (Ni), platinum (Pt), palladium (Pd), gold (Au), alloys thereof, or combinations thereof. In some embodiments, the circuit layer 130 is disposed around the periphery of the process working region 116. In some embodiments, the circuit layer 130 surrounds the process working region 116. In some embodiments, a vertical projection of the circuit layer 130 does not overlap with a vertical projection of the process working region 116.

The plurality of bonding pads 140 are disposed under the insulating layer 110 and electrically connected to the circuit layer 130, as shown in FIG. 1 and FIG. 2. To be specific, the plurality of bonding pads 140 are disposed on a side of the insulating layer 110 opposite to the light conversion layer 150, and extend into the insulating layer 110 to be electrically connected to the circuit layer 130. That is to say, the plurality of light emitting diodes 120 are electrically connected to the plurality of bonding pads 140 through the circuit layer 130. In some embodiments, the number of the bonding pads 140 is the same as the number of the sub-circuits of the circuit layer 130. For example, in this embodiment, the number of the bonding pads 140 is two, and the two bonding pads 140 are electrically connected to two sub-circuits of the circuit layer 130 respectively, as shown in FIG. 2.

In some embodiments, the material of the bonding pad 140 may include metal. For example, the metal material may include aluminum (Al), copper (Cu), indium (In), platinum (Pt), tin (Sn), gold (Au), zinc (Zn), titanium (Ti), silver (Ag), nickel (Ni), alloys thereof, or combinations thereof, but the disclosure is not limited thereto.

In some embodiments, in the cross-sectional view, any two adjacent electrodes 124 of any light emitting diode 120 have a first distance D1 in the horizontal direction, any two adjacent bonding pads 140 have a second distance D2 in the horizontal direction, and the second distance D2 is greater than the first distance D1. In some embodiments, the areas of the plurality of bonding pads 140 cover the areas of all the light emitting diodes 120 in the top view. In other words, the vertical projection of any light emitting diode 120 is located within the vertical projection of one of the bonding pads 140.

In some embodiments, the bonding pads 140 are disposed around the periphery of the process working region 116. In some embodiments, the plurality of bonding pads 140 is symmetrically disposed with the process working region 116 as the center. In some embodiments, a vertical projection of the bonding pad 140 does not overlap with a vertical projection of the process working region 116.

As shown in FIG. 1, the light conversion layer 150 is disposed on the insulating layer 110. Specifically, the light conversion layer 150 is disposed on the upper surface 113 of the insulating layer 110 and on the light emitting surfaces 122 of the light emitting diodes 120. In some embodiments, the light conversion layer 150 continuously covers all of the light emitting diodes 120. In other words, the light conversion layer 150 continuously spans across all the light emitting diodes 120, so that all the light emitting diodes 120 share one light conversion layer 150.

In some embodiments, the light conversion layer 150 includes a base material (not shown) and a luminescent material (not shown) distributed in the base material. The base material can be penetrated by the light emitted by the light emitting diodes 120, and the base material is, for example, resin, glass, ceramic, other suitable materials or a combination thereof. The light emitted by the light emitting diodes 120 has a penetration rate of not less than 80% through the base material, such as 80%, 85%, 90%, 95% or 100%. The luminescent material has the ability to absorb the light emitted by the light emitting diode 120 and re-emit the light after converting its wavelength. The luminescent material is, for example, phosphor or quantum dot (QD).

In some embodiments, the light conversion layer 150 has a second thickness T2, which is greater than the first thickness T1 of each light emitting diode 120, and the second thickness T2 is less than 200 micrometers. In some embodiments, when the second thickness T2 is less than a certain value, such as the first thickness T1, the support of the light emitting diode package 10 may be insufficient. On the contrary, in some embodiments, when the second thickness T2 is greater than a certain value, such as 200 micrometers, the transmittance of the light emitted by the light emitting diodes 120 will be affected. In some embodiments, the light conversion layer 150 may directly bond to the upper surface 113 of the insulating layer 110 and the light emitting surface 122 of each light emitting diode 120.

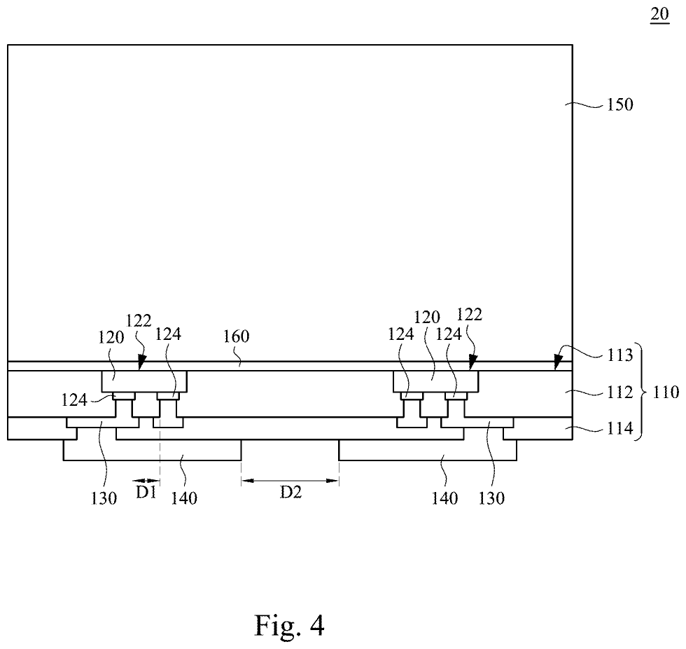

FIG. 4 is a cross-sectional view of a light emitting diode package according to various embodiments of the present disclosure. As shown in FIG. 4, the light emitting diode package 20 may further include an adhesive layer 160 disposed between the light conversion layer 150 and the light emitting surface 122 of each light emitting diode 120. To be specific, the adhesive layer 160 covers both the upper surface 113 of the insulating layer 110 and the light emitting surface 122 of each light emitting diode 120, and the adhesive layer 160 is covered by the light conversion layer 150, as shown in FIG. 4. The adhesive layer 160 can further enhance the bonding strength between the light conversion layer 150 and the upper surface 113 and the light emitting surface 122. In some embodiments, the adhesive layer 160 includes a light-transmitting material that can be penetrated by the light emitted by the light emitting diodes 120, such as polymide (PI), silicone, epoxy resin, other suitable adhesive materials, or a combination thereof. The transmittance of the adhesive layer 160 is not less than 80%, such as 80%, 85%, 90%, 95% or 100%.

In summary, the light emitting diode packaging structure of the present disclosure includes using a thin film light emitting diode to form a thin packaging structure, which is conducive to the application of thin devices, and through the redistribution layer (RDL) technology, the electrical contacts (electrodes) with relatively small areas and narrow gaps in the light emitting diode are extended through the circuit layer to the bonding pads with larger areas and wider gaps. This helps to reduce the difficulty of the bonding process of the small-size packaging structures. At the same time, the light emitting diodes and the circuit layer are arranged to surround the process working region located in the center of the packaging structure, which can further prevent the light emitting diodes and/or the circuit layer from being damaged in subsequent processes, thereby increasing the yield. For example, when the package is moved to the carrier for bonding using a jig, the jig can apply force to the process working region where the light emitting diode and the circuit layer are not disposed, and because the force application point is close to the geometric center of the package, the package can be evenly stressed and the balance of the package can be maintained when it moves. In addition, an insulating layer with a light-reflecting effect (such as a Bragg reflector) is disposed at the bottom of the packaging structure (near the bonding pad side), so that the light emitting efficiency can be improved.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A light emitting diode package, comprising:
an insulating layer, having a total area, and a process working region with an area which is 2% to 50% of the total area;
a plurality of light emitting diodes, embedded in the insulating layer, and arranged around the process working region;
a circuit layer, embedded in the insulating layer, and electrically connected to the plurality of light emitting diodes;
a plurality of bonding pads, disposed under the insulating layer, and electrically connected to the circuit layer; and
a light conversion layer, disposed on the insulating layer;
wherein, in a top view, the light emitting diode package structure has a geometric center overlapping the process working region.

2. The light emitting diode package of claim 1, wherein, the insulating layer has an upper surface, the plurality of light emitting diodes each comprises a light emitting surface which is leveled with the upper surface.

3. The light emitting diode package of claim 1, further comprising an adhesive layer disposed between the light conversion layer and the plurality of light emitting diodes.

4. The light emitting diode package of claim 1, wherein, the plurality of light emitting diodes each comprises a plurality of electrodes disposed on a side opposite to the light conversion layer, the plurality of electrodes comprises two adjacent electrodes separated by a first distance, the plurality of bonding pads comprises two adjacent bonding pads separated by a second distance greater than the first distance.

5. The light emitting diode package of claim 1, wherein the plurality of light emitting diodes each has a thickness of 3 micrometers to 20 micrometers.

6. The light emitting diode package of claim 1, wherein the insulating layer comprises a first insulating layer and a second insulating layer disposed below the first insulating layer, the plurality of light emitting diodes are embedded in the first insulating layer, and the circuit layer is embedded in the second insulating layer.

7. The light emitting diode package of claim 6, wherein the first insulating layer, the second insulating layer or both have a reflectivity greater than 80% with respect to light emitted by the plurality of light emitting diodes.

8. The light emitting diode package of claim 1, wherein the plurality of light emitting diodes comprises a first light emitting diode and a second light emitting diode that are separated from each other by an interval and symmetric with respect to the process working region.

9. The light emitting diode package of claim 1, wherein the plurality of the light emitting diodes comprises a light emitting diode with a first thickness, the light conversion layer has a second thickness greater than the first thickness and less than 200 micrometers.

10. The light emitting diode package of claim 1, wherein the light conversion layer continuously covers the plurality of light emitting diodes.

11. A light emitting diode package, comprising:
an insulating layer, having a total area, and a process working region with an area which is 2% to 50% of the total area;
a plurality of light emitting diodes, embedded in the insulating layer, and not overlapping the process working region with their vertical projections;
a circuit layer, embedded in the insulating layer, and electrically connected to the plurality of light emitting diodes;
a plurality of bonding pads, disposed under the insulating layer and electrically connected to the circuit layer; and
a light conversion layer, disposed on the insulating layer.

12. The light emitting diode package of claim 11, wherein, the insulating layer has an upper surface, the plurality of the light emitting diodes each has a light emitting surface which is leveled with the upper surface.

13. The light emitting diode package of claim 11, further comprising an adhesive layer disposed between the light conversion layer and the light emitting diodes.

14. The light emitting diode package of claim 11, wherein the plurality of light emitting diodes each comprises a plurality of electrodes disposed on a side opposite to the light conversion layer, the plurality of electrodes comprises two adjacent electrodes separated by a first distance, the plurality of bonding pads comprises two adjacent bonding pads separated by a second distance greater than the first distance.

15. The light emitting diode package of claim 11, wherein the plurality of the light emitting diodes each has a thickness of 3 micrometers to 20 micrometers.

16. The light emitting diode package of claim 11, wherein the insulating layer comprises a first insulating layer and a second insulating layer disposed below the first insulating layer, the plurality of light emitting diodes are embedded in the first insulating layer, and the circuit layer is embedded in the second insulating layer.

17. The light emitting diode package of claim 16, wherein the first insulating layer, the second insulating layer or both have a reflectivity greater than 80% with respect to light emitted by the plurality of light emitting diodes.

18. The light emitting diode package of claim 11, wherein the plurality of light emitting diodes comprises a first light emitting diode and a second light emitting diode that are separated from each other by an interval and symmetric with respect to the process working region.

19. The light emitting diode package of claim 11, wherein the plurality of the light emitting diodes comprises a light emitting diode with a first thickness, the light conversion layer has a second thickness greater than the first thickness and less than 200 micrometers.

20. The light emitting diode package of claim 11, wherein the light conversion layer continuously covers the plurality of light emitting diodes.
